(19) United States
(12) Patent Application Publication
(10) Pub. No.: US 2026/0261261 A1
(43) Pub. Date: Sep. 3, 2026

(54) CONTROL CIRCUIT AND CONTROL METHOD

(71) Applicant: CHENGDU CONVENIENTPOWER SEMICONDUCTOR CO., LTD., Sichuan (CN)

(72) Inventors: Bo CAI, Sichuan (CN); Jian QING, Sichuan (CN); Li ZHANG, Sichuan (CN)

(73) Assignee: CHENGDU CONVENIENTPOWER SEMICONDUCTOR CO., LTD., Sichuan (CN)

(21) Appl. No.: 19/122,715

(22) PCT Filed: Aug. 31, 2023
(86) PCT No.: PCT/CN2023/116227

§ 371 Date: Apr. 18, 2025

(30) Foreign Application Priority Data
Oct. 25, 2022 (CN) 202211306384.0

(51) Int. Cl. H03K 17/16; H03K 17/08; H03K 17/082

(52) U.S. Cl. CPC H03K 17/161; H03K 17/0822; H03K 2017/0806

(57) ABSTRACT

Control circuit and control method are provided. Circuit includes: gallium nitride power device, detection module, first unidirectional conducting device, first sampling module and control current source. First input end of control current source is connected to gate source current. Output end of control current source is connected to gate of gallium nitride power device. Drain of gallium nitride power device is connected to power supply. Source of gallium nitride power device is connected to load. Input end of detection module is connected to load. Output end of detection module is connected to cathode of first unidirectional conducting device. Anode of first unidirectional conducting device is connected to control current source, gate and source of gallium nitride power device. First sampling module is connected between control current source and first unidirectional conducting device. Second input end of control current source is connected to output end of first sampling module.

### CROSS-REFERENCE TO RELATED APPLICATIONS

The present disclosure claims the priority to the Chinese patent application with the filling No. 202211306384.0 filed with the Chinese Patent Office on Oct. 25, 2022, and entitled “CONTROL CIRCUIT AND CONTROL METHOD”, the contents of which are incorporated herein by reference in entirety.

### TECHNICAL FIELD

The present disclosure relates to the technical field of circuits, and particularly, to a control circuit and a control method.

### BACKGROUND ART

With the development of semiconductor technologies, the types of power devices have shifted from silicon-based semiconductors to new types of gallium nitride (GaN) semiconductors.

In the application of energy storage power supplies, it is necessary to adjust a power of a system by adjusting conducting impedance(s) of power transistor(s) to enable the system to reach a steady state.

However, due to a fact that a gate leakage current of a gallium nitride-based power device is much greater than that of a traditional silicon-based semiconductor, with the gate leakage current increasing from a nanoampere level to a microampere level, a closed-loop regulation accuracy of the system is reduced.

### SUMMARY

It is an object of the present disclosure, in view of the above deficiency in the prior art, to provide a control circuit and a control method, so as to improve a closed-loop control accuracy and achieve a precise closed-loop control of a load.

In order to achieve the above object, technical solutions in embodiments of the present disclosure are as follows.

In a first aspect, a control circuit is provided in an embodiment of the present disclosure. The control circuit comprises a gallium nitride power device, a detection module, a first unidirectional conduction device, first sampling module, and a controlled current source.

A first input terminal of the controlled current source is connected to a source current of gate, and an output terminal of the controlled current source is connected to a gate of the gallium nitride power device to control a gate voltage of the gallium nitride power device.

A drain of the gallium nitride power device is connected to a power supply, and a source of the gallium nitride power device is connected to a load, so as to adjust an output power of the load according to the gate voltage of the gallium nitride power device.

An input terminal of the detection module is connected to the load, so as to detect a state of the load and determine whether the load reaches a preset state according to a detected state value and a reference state value.

An output terminal of the detection module is connected to a cathode of the first unidirectional conduction device to allow the first unidirectional conduction device to conduct when the load is determined to reach the preset state.

An anode of the first unidirectional conduction device is respectively connected to the controlled current source, and the gate and the source of the gallium nitride power device, and the first sampling module is connected between the controlled current source and the first unidirectional conduction device to sample a current flowing through the first unidirectional conduction device.

A second input terminal of the controlled current source is connected to an output terminal of the first sampling module to adjust the source current of gate according to the current flowing through the first unidirectional conduction device, so that the current flowing through the first unidirectional conduction device is equal to the source current of gate, thereby enabling the load to maintain the preset state.

Optionally, the detection module comprises an output voltage sampling unit and a voltage error amplifier.

Input terminals of the output voltage sampling unit are respectively connected to two terminals of the load to sample an output voltage of the load.

An output terminal of the output voltage sampling unit is connected to a negative input terminal of the voltage error amplifier, a positive input terminal of the voltage error amplifier is used to receive an input reference voltage value, and an output terminal of the voltage error amplifier is connected to the cathode of the first unidirectional conduction device, so as to determine that the load reaches the preset state when a sampled voltage value of the load is equal to the reference voltage value.

Optionally, the detection module comprises an output current sampling unit and a current error amplifier, and the control circuit further comprises a resistor.

The resistor is connected between the load and the ground, input terminals of the output current sampling unit are respectively connected to two terminals of the resistor to sample an output current of the load.

An output terminal of the output current sampling unit is connected to a negative input terminal of the current error amplifier, a positive input terminal of the current error amplifier is used to receive an input reference current value, and an output terminal of the current error amplifier is connected to the cathode of the first unidirectional conduction device, so as to determine that the load reaches the preset state when a sampled current value of the load is equal to the reference current value.

Optionally, the detection module comprises a temperature sampling unit and a temperature error amplifier.

The temperature sampling unit is used to sample a temperature of the load, an output terminal of the temperature sampling unit is connected to a negative input terminal of the temperature error amplifier, a positive input terminal of the temperature error amplifier is used to receive an input reference temperature value, and an output terminal of the temperature error amplifier is connected to the cathode of the first unidirectional conduction device, so as to determine that the load reaches the preset state when a sampled temperature value of the load is equal to the reference temperature value.

Optionally, the control circuit further comprises a second sampling module, a second error amplifier and a second unidirectional conduction device.

Input terminals of the second sampling module are respectively connected to the drain and the source of the gallium nitride power device to form a parallel connection, an output terminal of the second sampling module is connected to a negative input terminal of the second error amplifier, a positive input terminal of the second error amplifier is used to receive an input reference current value, and an output terminal of the second error amplifier is connected to a cathode of the second unidirectional conduction device, so as to determine that the load reaches the preset state when a sampled current value of the gallium nitride power device is equal to the reference current value.

Optionally, the input terminals of the second sampling module are connected in parallel between the source of the gallium nitride power device and the ground, the output terminal of the second sampling module is connected to the negative input terminal of the second error amplifier, the positive input terminal of the second error amplifier is used to receive an input reference voltage value, and the output terminal of the second error amplifier is connected to the cathode of the second unidirectional conduction device, so as to determine that the load reaches the preset state when a sampled voltage value of the gallium nitride power device is equal to the reference voltage value.

In a second aspect, a control method is provided in an embodiment of the present disclosure, and the control method is applied to any control circuit in the first aspect. The control circuit comprises the gallium nitride power device, the detection module, the first unidirectional conduction device, the first sampling module, and the controlled current source. The control method comprises:
controlling, by the controlled current source, the gate voltage of the gallium nitride power device according to the source current of gate, so as to adjust the output power of the load according to the gate voltage of the gallium nitride power device;
detecting, by the detection module, the state of the load, and determining, by the detection module, that the load reaches the preset state according to the detected state value and the reference state value, so as to allow the first unidirectional conduction device to conduct;
sampling, by the first sampling module, the current flowing through the first unidirectional conduction device; and
adjusting, by the controlled current source, the source current of gate according to the current flowing through the first unidirectional conduction device, so that the current flowing through the first unidirectional conduction device is equal to the source current of gate, thereby enabling the load to maintain the preset state.

Optionally, if the detection module comprises an output voltage sampling unit and a voltage error amplifier, the step of detecting, by the detection module, the state of the load, and determining, by the detection module, that the load reaches the preset state according to the detected state value and the reference state value, so as to allow the first unidirectional conduction device to conduct, comprises:
sampling, by the output voltage sampling unit, an output voltage of the load;
determining, by the voltage error amplifier, that the load reaches the preset state when a sampled voltage value of the load is equal to a reference voltage value; and
controlling, by the voltage error amplifier, the first unidirectional conduction device to conduct.

Optionally, if the detection module comprises an output current sampling unit and a current error amplifier, the step of detecting, by the detection module, the state of the load, and determining, by the detection module, that the load reaches the preset state according to the detected state value and the reference state value, so as to allow the first unidirectional conduction device to conduct, comprises:
sampling, by the output current sampling unit, an output current of the load;
determining, by the current error amplifier, that the load reaches the preset state when a sampled current value of the load is equal to a reference current value; and
controlling, by the current error amplifier, the first unidirectional conduction device to conduct.

Optionally, if the detection module comprises a temperature sampling unit and a temperature error amplifier, the step of detecting, by the detection module, the state of the load, and determining, by the detection module, that the load reaches the preset state according to the detected state value and the reference state value, so as to allow the first unidirectional conduction device to conduct, comprises:
sampling, by the temperature sampling unit, a temperature of the load;
determining, by the temperature error amplifier, that the load reaches the preset state when a sampled temperature value of the load is equal to a reference temperature value; and controlling, by the temperature error amplifier, the first unidirectional conduction device to conduct.

Optionally, if the control circuit further comprises a second sampling module, a second error amplifier and a second unidirectional conduction device, and input terminals of the second sampling module are respectively connected to the gate and the source of the gallium nitride power device, the control method further comprises:
sampling, by the second sampling module, a drain-source current of the gallium nitride power device;
determining, by the second error amplifier, that the load reaches the preset state when a sampled current value of the gallium nitride power device is equal to a reference current value;
controlling, by the second error amplifier, the second unidirectional conduction device to conduct;
sampling, by the first sampling module, a current flowing through the second unidirectional conduction device; and
adjusting, by the controlled current source, the source current of gate according to the current flowing through the second unidirectional conduction device, so that the current flowing through the second unidirectional conduction device is equal to the source current of gate, thereby enabling the load to maintain the preset state.

Optionally, the input terminals of the second sampling module are connected between the source of the gallium nitride power device and the ground, and the control method further comprises:
sampling, by the second sampling module, a source voltage of the gallium nitride power device;
determining, by the second error amplifier, that the load reaches the preset state when a sampled voltage value of the gallium nitride power device is equal to a reference voltage value;
controlling, by the second error amplifier, the second unidirectional conduction device to conduct;
sampling, by the first sampling module, a voltage flowing through the second unidirectional conduction device; and
adjusting, by the controlled current source, the source current of gate according to the current flowing through the second unidirectional conduction device, so that the current flowing through the second unidirectional conduction device is equal to the source current of gate, thereby enabling the load to maintain the preset state.

Beneficial effects of the present disclosure are as follows.

A control circuit and a control method are provided in the present disclosure. When the detection module detects that the detected state value of the load is equal to the reference state value, the detection module controls the first unidirectional conduction device to conduct. The first sampling module samples the current flowing through the first unidirectional conduction device, and the controlled current source adjusts the source current of gate based on the current flowing through the first unidirectional conduction device, which ensures that the current flowing through the first unidirectional conduction device is equal to the source current of gate, so as to control the gate voltage of the gallium nitride power device to remain steady after the first unidirectional conduction device conducts. Therefore, the load maintains the preset state, so that an influence of the gate leakage current of the gallium nitride power device on the current flowing through the first unidirectional conduction device is avoided, and an error between the detected state value of the load when reaching a steady state and the reference state value caused by the gate leakage current is thus avoided, thereby improving a control accuracy of the control circuit and achieving a precise closed-loop control for the load.

### BRIEF DESCRIPTION OF DRAWINGS

In order to illustrate the technical solutions of the embodiments of the present disclosure more clearly, the drawings that need to be used in the embodiments will be briefly introduced below. It should be understood that the following drawings only show some embodiments of the present disclosure, and therefore should not be regarded as limitation to the scope. For those ordinarily skilled in the art, other related drawings may also be obtained from these drawings without creative efforts.

FIG. 1 is a schematic diagram of a control circuit based on a conventional power device;

FIG. 2 is a schematic diagram of a control circuit based on a gallium nitride power device;

FIG. 3 is a schematic diagram of a control circuit provided in an embodiment of the present disclosure;

FIG. 4 is a schematic diagram of another control circuit provided in an embodiment of the present disclosure;

FIG. 5 is a schematic flowchart of a control method provided in an embodiment of the present disclosure;

FIG. 6 is a schematic diagram of yet another control circuit provided in an embodiment of the present disclosure;

FIG. 7 is a schematic flowchart of another control method provided in an embodiment of the present disclosure;

FIG. 8 is a schematic flowchart of yet another control method provided in an embodiment of the present disclosure;

FIG. 9 is a schematic flowchart of yet another control method provided in an embodiment of the present disclosure;

FIG. 10 is a schematic diagram of yet another control circuit provided in an embodiment of the present disclosure;

FIG. 11 is a schematic flowchart of yet another control method provided in an embodiment of the present disclosure;

FIG. 12 is a schematic diagram of yet another control circuit provided in an embodiment of the present disclosure;

FIG. 13 is a schematic flowchart of yet another control method provided in an embodiment of the present disclosure;

FIG. 14 is a schematic simulation diagram based on an existing control circuit of a gallium nitride power device; and

FIG. 15 is a schematic simulation diagram based on a control circuit of a gallium nitride power device in an embodiment of the present disclosure.

### DETAILED DESCRIPTION OF EMBODIMENTS

In order to make the objectives, technical solutions and advantages of the embodiments of the present disclosure clearer, the technical solutions in the embodiments of the present disclosure will be clearly and completely described below with reference to the drawings in the embodiments of the present disclosure, obviously, the embodiments described are only part of the embodiments of the present disclosure, rather than all embodiments.

Therefore, the following detailed description of the embodiments of the present disclosure provided in the drawings is not intended to limit the scope of the claimed present disclosure, but merely represents selected embodiments of the present disclosure. Based on the embodiments in the present disclosure, all other embodiments obtained by those ordinarily skilled in the art without creative efforts fall within the protection scope of the present disclosure.

In addition, the terms such as “first” and “second” in the description, the claims and the above-mentioned drawings of the present disclosure are used to distinguish similar objects, and are not necessarily used to describe a particular sequence or order of precedence. It should be understood that ordinal numerals used in this way may be interchanged where appropriate, so that the embodiments of the present disclosure described herein may be implemented in order(s) in addition to those illustrated or described herein. Moreover, the terms “include” and “have” and any variations thereof are intended to cover non-exclusive inclusions, for example, a process, method, system, product or device that includes a series of steps or units is not necessarily limited to those steps or units clearly listed, but may include other steps or units that are not clearly listed or are inherent to these processes, methods, products or devices.

It should be noted that the features in the embodiments of the present disclosure may be combined with each other without conflict.

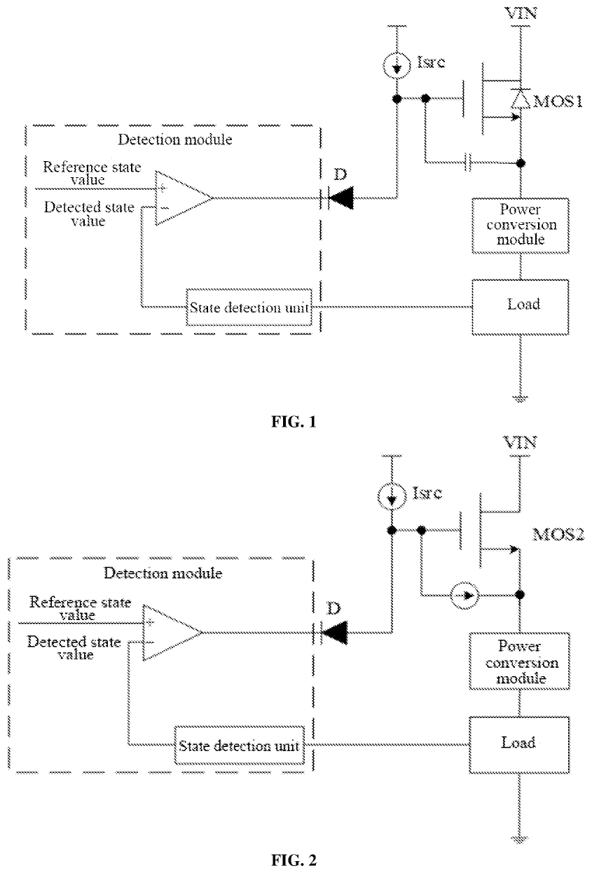

Referring to FIG. 1, FIG. 1 is a schematic diagram of a control circuit based on a conventional power device. As shown in FIG. 1, a source current of gate Isrc provides a gate current for the conventional power device MOS1. After the conventional power device MOS1 conducts, a conducting impedance of the conventional power device MOS1 continuously decreases as a gate voltage of the conventional power device MOS1 increases. A power supply Vin supplies power to a load through the conventional power device MOS1 and a power conversion module. A state of the load is detected by a detection module, and a detected state value is amplified based on an amplification factor of an error amplifier in the detection module when the detected state value is determined to be equal to a reference state value, so that a low level is output from the detection module, and a unidirectional conduction device D conducts. In a state where the unidirectional conduction device D conducts, the gate voltage of the conventional power device MOS1 remains constant, and the conducting impedance of the conventional power device MOS1 is unchanged, so that the load maintains a steady state.

Due to a very low gate leakage current of the conventional power device MOS1, a current flowing through the unidirectional conduction device D is the source current of gate Isrc. Based on the source current of gate Isrc and the amplification factor provided by the error amplifier in the detection module, a low level may be output when the detected state value is equal to the reference state value to stop supplying power to the load, so that the state of the load reaches the reference state value of the steady state, thereby achieving the steady state of the load.

However, with the development of semiconductor technologies, the types of power devices have shifted from silicon-based semiconductors to new types of gallium nitride (GaN) semiconductors, and the conventional power device in the control circuit has also become a gallium nitride power device. Referring to FIG. 2, FIG. 2 is a schematic diagram of a control circuit based on a gallium nitride power device. As shown in FIG. 2, when a source current of gate Isrc provides a gate current for the gallium nitride power device MOS2, a leakage current Ileak is generated between a gate and a source of the gallium nitride power device MOS2, and the gate leakage current changes with a temperature and a gate voltage of the gallium nitride power device. After a unidirectional conduction device D conducts as a result of a detected state value being equal to a reference state value, a current flowing through the unidirectional conduction device D has a value of Isrc minus Ileak (Isrc-Ileak). Due to a limited gain gm of an error amplifier in a detection module, the gate leakage current causes an additional system error Ileak/gm at an input terminal of the error amplifier. In order to ensure the stability of the control circuit, a transconductance gain of the error amplifier is limited and cannot be infinite, resulting in the non-negligible system error Ileak/gm. An error generated based on the leakage current Ileak has an influence on a closed-loop regulation accuracy of the control circuit, so that although a load seemingly reaches a steady state, there is an error between the detected state value and the reference state value in its steady state, that is, the control circuit cannot achieve a precise closed-loop control of the load.

Based on this, a control circuit and a control method of the embodiments of the present disclosure are provided. By eliminating an influence of a gate leakage current on a detection accuracy of a detection module, it is ensured that the detection module may control a first unidirectional conduction device to conduct when the detection module detects that a detected state value of a load is equal to a reference state value, so that a gate voltage of a gallium nitride power device remains steady, and a conducting impedance of the gallium nitride power device remains unchanged, thereby causing the load to maintain a steady state. Since the influence of the gate leakage current is eliminated, there is no error between the detected state value of the load when reaching the steady state and the reference state value, which improves a control accuracy of the control circuit, thereby achieving a precise closed-loop control of the load.

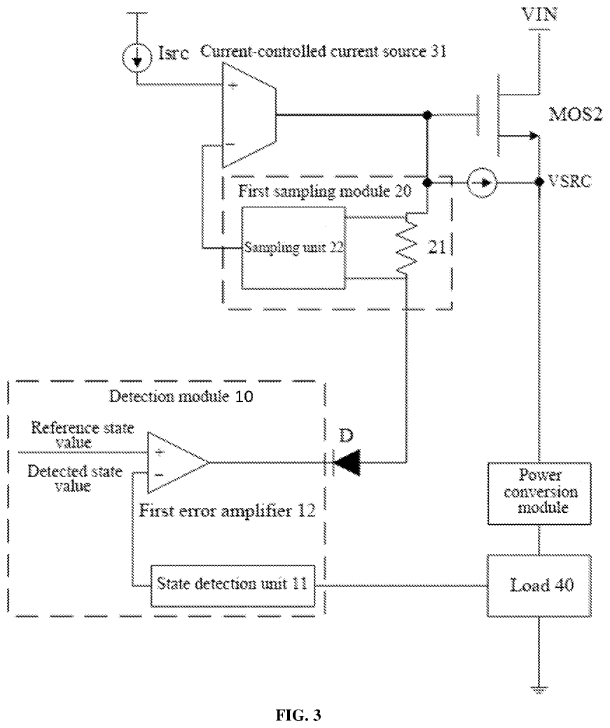

Referring to FIG. 3, FIG. 3 is a schematic diagram of a control circuit provided in an embodiment of the present disclosure. As shown in FIG. 3, the control circuit includes a gallium nitride power device MOS2, a detection module 10, a first diode D1, a first sampling module 20, and a current-controlled current source 31.

A first input terminal of the current-controlled current source 31 is connected to a source current of gate Isrc, and an output terminal of the current-controlled current source 31 is connected to a gate of the gallium nitride power device MOS2 to control a gate voltage of the gallium nitride power device MOS2. A drain of the gallium nitride power device MOS2 is connected to a power supply VIN, and a source of the gallium nitride power device MOS2 is connected to a positive terminal of a load 40, so as to adjust an output power of the load 40 according to the gate voltage of the gallium nitride power device MOS2.

An input terminal of the detection module 10 is connected to the load 40, so as to detect a state of the load 40 and determine whether the load 40 reaches a preset state according to a detected state value SNS and a reference state value REG_REF. An output terminal of the detection module 10 is connected to a cathode of the first diode D1 to allow the first diode D1 to conduct when the load 40 is determined to reach the preset state.

An anode of the first diode D1 is respectively connected to the current-controlled current source 31, and the gate and the source of the gallium nitride power device MOS2. The first sampling module 20 is connected between the current-controlled current source 31 and the first diode D1 to sample a current flowing through the first diode D1. A second input terminal of the current-controlled current source 31 is connected to an output terminal of the first sampling module 20 to adjust the source current of gate Isrc according to the current flowing through the first diode D1, so that the current flowing through the first diode D1 is equal to the source current of gate Isrc, thereby enabling the load 40 to maintain the preset state.

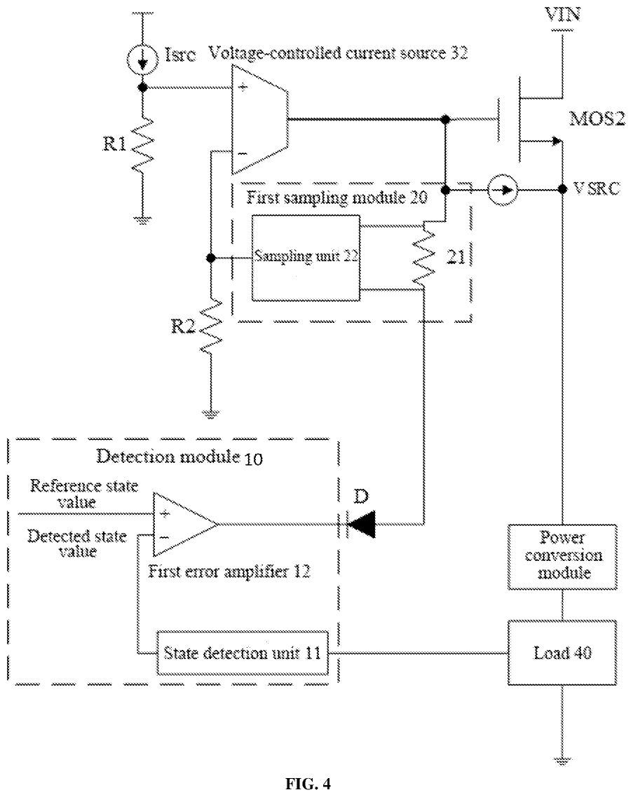

In a possible implementation, Referring to FIG. 4, FIG. 4 is a schematic diagram of another control circuit provided in an embodiment of the present disclosure. As shown in FIG. 4, the control circuit includes a gallium nitride power device MOS2, a detection module 10, a first diode D1, a first sampling module 20, and a voltage-controlled current source 32.

The first sampling module 20 is a voltage sampling module when the controlled current source is the voltage-controlled current source 32. A source current of gate Isrc is grounded through a resistor R1, and an output terminal of the first sampling module 20 is grounded through a resistor R2. A positive input terminal of the voltage-controlled current source 32 is connected between the source current of gate Isrc and the resistor R1, and a negative input terminal of the voltage-controlled current source 32 is connected between the first sampling module 20 and the resistor R2. Other connections are the same as those in FIG. 3, and will not be repeated here. It should be noted that, in addition to the diode shown in FIG. 3 or FIG. 4, the first unidirectional conduction device may also be other device with a unidirectional current direction, such as a metal-oxide-semiconductor (MOS) transistor or a triode, which is not limited in this embodiment.

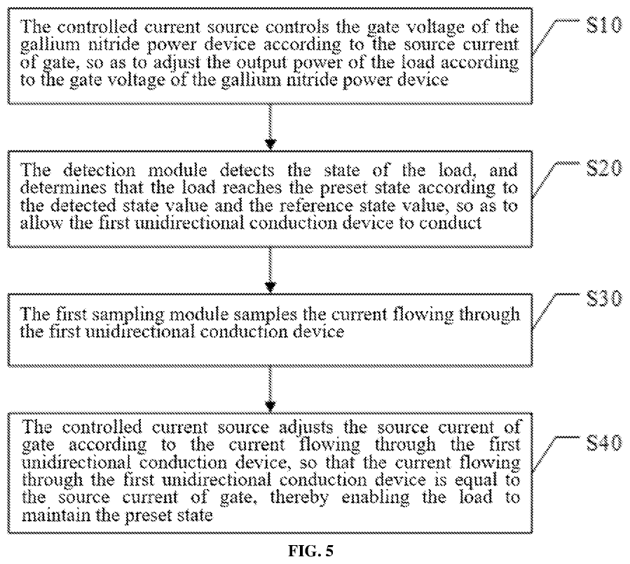

Based on the above control circuit shown in FIG. 3 or FIG. 4, a control method applied to the above control circuit is further provided in an embodiment of the present disclosure. Referring to FIG. 5, FIG. 5 is a schematic flowchart of a control method provided in an embodiment of the present disclosure. As shown in FIG. 5, the method may include S10 to S40.

In S10, the controlled current source controls the gate voltage of the gallium nitride power device according to the source current of gate, so as to adjust the output power of the load according to the gate voltage of the gallium nitride power device.

In S20, the detection module detects the state of the load, and determines that the load reaches the preset state according to the detected state value and the reference state value, so as to allow the first unidirectional conduction device to conduct.

In S30, the first sampling module samples the current flowing through the first unidirectional conduction device.

In S40, the controlled current source adjusts the source current of gate according to the current flowing through the first unidirectional conduction device, so that the current flowing through the first unidirectional conduction device is equal to the source current of gate, thereby enabling the load to maintain the preset state.

In this embodiment, as shown in FIGS. 3, 4, and 5, the controlled current source outputs a gate control current according to the source current of gate. After the gallium nitride power device conducts, the gate voltage of the gallium nitride power device rises as the source current of gate increases, and the conducting impedance of the gallium nitride power device decreases, so that the power supply VIN supplies power to the load through the gallium nitride power device.

The preset state may be a preset steady state or a preset safety critical state of the load. The detection module 10 compares the detected state value of the load 40 that is detected with the reference state value, and compensates the detected state value with a preset amplification factor. When the detected state value is less than the reference state value, the load does not reach the preset state, and the detected state value is still less than the reference state value due to a compensation value, so that the detection module 10 outputs a high level, and the first diode D1 cannot conduct. When the detected state value is equal to the reference state value, the load reaches the preset state, and the detected state value is enabled to be greater than the reference state value through compensation, so that the detection module 10 outputs a low level, and the first diode D1 conducts.

After the first diode D1 conducts, the first sampling module 20 detects the current flowing through the first diode D1 and transmits a detected current value to the controlled current source 30. The controlled current source 30 adjusts the source current of gate according to the current flowing through the first diode D1, so that an output current may eliminate the influence of the gate leakage current Ileak, which ensures that the current flowing through the first diode D1 is equal to the source current of gate Isrc when the first diode D1 conducts. Therefore, there is no error in the current flowing through the first diode D1, and the gate voltage of the gallium nitride power device MOS2 is pulled down and remains constant, thereby enabling the conducting impedance of the gallium nitride power device MOS2 to be unchanged, which ensures that the detected state value of the load when reaching the preset state is equal to the reference state value, and there is no error between the detected state value and the reference state value.

In a possible implementation, as shown in FIGS. 3 or 4, the detection module 10 includes a state detection unit 11 and a first error amplifier 12. An output terminal of the state detection unit 11 is connected to a negative input terminal of the first error amplifier 12, a positive input terminal of the first error amplifier 12 is used to receive an input reference state value, and an output terminal of the first error amplifier 12 is connected to the cathode of the first diode D1. When the detected state value is less than the reference state value, the load does not reach the preset state, so that the first error amplifier 12 outputs a high level, and the first diode D1 does not conduct. When the detected state value is equal to the reference state value, the load reaches the preset state, and the detected state value is enabled to be greater than the reference state value through compensation, so that the first error amplifier 12 outputs a low level, and the first diode D1 conducts. Therefore, the gate voltage of the gallium nitride power device MOS2 is pulled down and remains constant, thereby enabling the conducting impedance of the gallium nitride power device MOS2 to be unchanged, which ensures that the detected state value of the load when reaching the preset state is equal to the reference state value, and there is no error between the detected state value and the reference state value.

In a possible implementation, as shown in FIGS. 3 or 4, the first sampling module 20 includes a sampling resistor 21 and a sampling unit 22. The sampling resistor 21 is connected between the controlled current source 30 and the first diode D1. Input terminals of the sampling unit 22 are respectively connected to two terminals of the sampling resistor 21 to form a parallel connection. The current flowing through the first diode D1 when the first diode D1 conducts is determined according to a current flowing through the sampling resistor 21. An output terminal of the sampling unit 22 is connected to a negative input terminal of the controlled current source 30, and the source current of gate Isrc is connected to a positive input terminal of the controlled current source 30, so that the controlled current source 30 adjusts the source current of gate Isrc according to the current flowing through the first diode D1 and sampled by the sampling unit 22, thereby ensuring that the current flowing through the first diode D1 in the output current of the controlled current source 30 is equal to the source current of gate Isrc. That is, the current flowing through the first diode D1 is ensured not to be influenced by the gate leakage current Ileak, resulting in no error at the input terminal of the first error amplifier 12, thereby ensuring that the detected state value of the load when reaching the steady state is equal to the reference state value.

In some embodiments, in addition to using the sampling resistor to sample the current flowing through the first diode, a sampling power transistor, for example, may also be used to sample the current flowing through the first diode.

In a possible implementation, a power conversion module is provided between the gallium nitride power device and the load, and is used to convert the power supply into a power supply that may supply power to the load. For example, the power conversion module may be a power conversion module with resistive characteristics (linear charger) or equivalent resistive characteristics (switched capacitor), such as a switched capacitor converter, etc., which is not limited in this embodiment.

In the control circuit and the control method provided in the above embodiments, the detection module controls the first unidirectional conduction device to conduct when the detection module detects that the detected state value of the load is equal to the reference state value. The first sampling module samples the current flowing through the first unidirectional conduction device, and the controlled current source adjusts the source current of gate based on the current flowing through the first unidirectional conduction device, so as to ensure that the current flowing through the first unidirectional conduction device is equal to the source current of gate, thereby controlling the gate voltage of the gallium nitride power device to remain steady after the first unidirectional conduction device conducts, so that the load maintains the preset state. Therefore, the influence of the gate leakage current of the gallium nitride power device on the current flowing through the first unidirectional conduction device is avoided, so that the error between the detected state value of the load when reaching the steady state and the reference state value caused by the gate leakage current is avoided, which improves the control accuracy of the control circuit, thereby achieving the precise closed-loop control of the load.

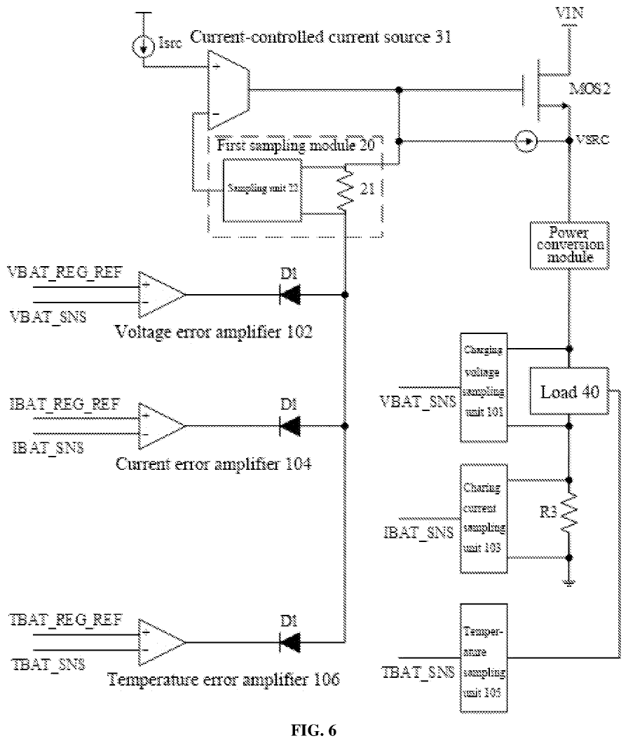

Based on the above embodiments, yet another control circuit is provided in an embodiment of the present disclosure. Referring to FIG. 6, FIG. 6 is a schematic diagram of yet another control circuit provided in an embodiment of the present disclosure. As shown in FIG. 6, the detection module 10 includes an output voltage sampling unit 101 and a voltage error amplifier 102.

Input terminals of the output voltage sampling unit 101 are respectively connected to two terminals of the load 40 to sample an output voltage of the load 40, and an output terminal of the output voltage sampling unit 101 is connected to a negative input terminal of the voltage error amplifier 102. A positive input terminal of the voltage error amplifier 102 is used to receive an input reference voltage value VBAT_REG_REF, and an output terminal of the voltage error amplifier 102 is connected to the cathode of the first diode D1, so as to determine that the load 40 reaches the preset state when a sampled voltage value VBAT_SNS of the load 40 is equal to the reference voltage value VBAT_REG_REF.

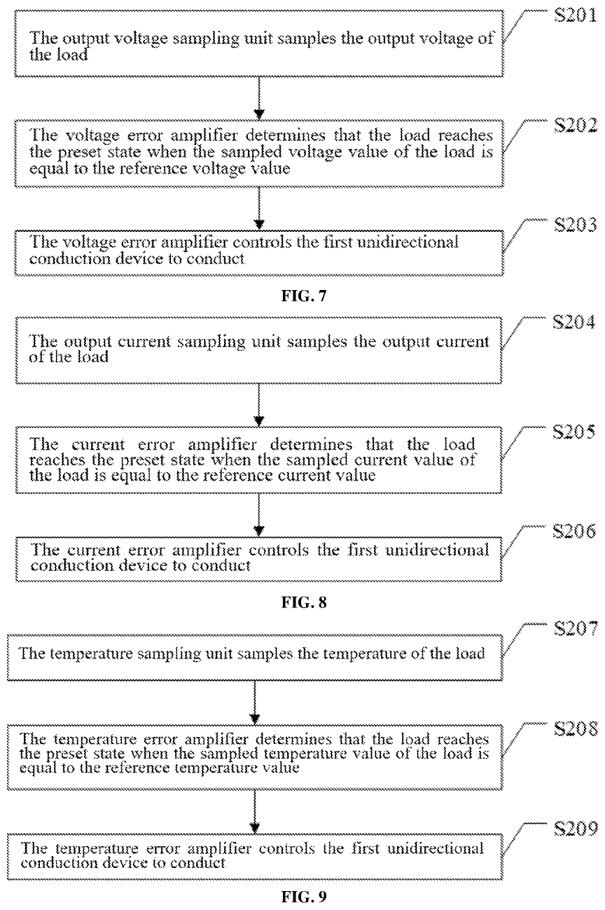

Based on the above control circuit, a control method applied to the above control circuit is further provided in an embodiment of the present disclosure. Referring to FIG. 7, FIG. 7 is a schematic flowchart of another control method provided in an embodiment of the present disclosure. As shown in FIG. 7, S20 above may include S201 to S203.

In S201, the output voltage sampling unit samples the output voltage of the load.

In S202, the voltage error amplifier determines that the load reaches the preset state when the sampled voltage value of the load is equal to the reference voltage value.

In S203, the voltage error amplifier controls the first unidirectional conduction device to conduct.

In this embodiment, as shown in FIGS. 6 and 7, the preset state is a constant-voltage state where the output voltage of the load 40 reaches a preset reference voltage. The output voltage sampling unit 101 detects the output voltage of the load 40, and the voltage error amplifier 102 outputs a high level when the voltage error amplifier 102 determines that the detected voltage value VBAT_SNS is less than the reference voltage value VBAT_REG_REF, so that the first diode D1 is cut off. When the voltage error amplifier 102 determines that the detected voltage value VBAT_SNS is equal to the reference voltage value VBAT_REG_REF, the voltage error amplifier 102 outputs a dedicated level based on a compensation value, so that the first diode D1 conducts. Therefore, the gate voltage of the gallium nitride power device MOS2 is pulled down and remains constant, thereby enabling the conducting impedance of the gallium nitride power device MOS2 to be unchanged, which ensures that the detected voltage value of the load when reaching the constant-voltage state is equal to the reference voltage value, and there is no error between the detected voltage value and the reference voltage value. Due to the adjustment of the controlled current source 30, after the first diode D1 conducts, the current flowing through the first diode D1 is equal to the source current of gate Isrc, so that an error in the detected voltage value caused by the gate leakage current Ileak is avoided, and the output voltage of the load 40 when reaching the constant-voltage state is equal to the reference voltage value, thereby achieving the constant-voltage of the load 40.

In the control circuit and the control method provided in the above embodiments, the voltage error amplifier controls the first unidirectional conduction device to conduct when the voltage error amplifier determines that the detected voltage value of the load is equal to the reference voltage value. The first sampling module samples the current flowing through the first unidirectional conduction device, and the controlled current source adjusts the source current of gate based on the current flowing through the first unidirectional conduction device, so as to ensure that the current flowing through the first unidirectional conduction device is equal to the source current of gate. Therefore, the error between the detected voltage value of the load when reaching the steady state and the reference voltage value caused by the gate leakage current of the gallium nitride power device is avoided, which ensures that the detected voltage value of the load when reaching the steady state is equal to the reference voltage value, and improves the closed-loop control accuracy of the constant-voltage control of the control circuit, thereby achieving the precise closed-loop control of the load.

In a possible implementation, as shown in FIG. 6, the detection module 10 includes an output current sampling unit 103 and a current error amplifier 104, and the control circuit further includes a resistor R3.

The resistor R3 is connected between the load 40 and the ground GND. Input terminals of the output current sampling unit 103 are respectively connected to two terminals of the resistor R3 to sample an output current of the load 40, and an output terminal of the output current sampling unit 103 is connected to a negative input terminal of the current error amplifier 104. A positive input terminal of the current error amplifier 104 is used to receive an input reference current value, and an output terminal of the current error amplifier 104 is connected to the cathode of the first diode D1, so as to determine that the load 40 reaches the preset state when a sampled current value of the load 40 is equal to the reference current value.

Based on the above control circuit, a control method applied to the above control circuit is further provided in an embodiment of the present disclosure. Referring to FIG. 8, FIG. 8 is a schematic flowchart of yet another control method provided in an embodiment of the present disclosure. As shown in FIG. 8, S20 above may include S204 to S206.

In S204, the output current sampling unit samples the output current of the load.

In S205, the current error amplifier determines that the load reaches the preset state when the sampled current value of the load is equal to the reference current value.

In S206, the current error amplifier controls the first unidirectional conduction device to conduct.

In this embodiment, as shown in FIGS. 6 and 8, the preset state is a constant-current state where the output current of the load 40 reaches a preset reference current. The output current sampling unit 103 detects the output current of the load 40, and the current error amplifier 104 outputs a high level when the current error amplifier 104 determines that the detected current value IBAT_SNS is less than the reference current value IBAT_REG_REF, so that the first diode D1 is cut off. When the current error amplifier 104 determines that the detected current value IBAT_SNS is equal to the reference current value IBAT_REG_REF, the current error amplifier 104 outputs a dedicated level based on a compensation value, so that the first diode D1 conducts. Therefore, the gate voltage of the gallium nitride power device MOS2 is pulled down and remains constant, thereby enabling the conducting impedance of the gallium nitride power device MOS2 to be unchanged, which ensures that the detected current value of the load when reaching the constant-current state is equal to the reference current value, and there is no error between the detected current value and the reference current value. Due to the adjustment of the controlled current source 30, after the first diode D1 conducts, the current flowing through the first diode D1 is equal to the source current of gate Isrc, so that an error in the detected current value caused by the gate leakage current Ileak is avoided, and the output current of the load 40 when reaching the steady state reaches the reference current value, thereby achieving the constant-current of the load 40.

In the control circuit and the control method provided in the above embodiments, the current error amplifier controls the first unidirectional conduction device to conduct when the current error amplifier determines that the detected current value of the load is equal to the reference current value. The first sampling module samples the current flowing through the first unidirectional conduction device, and the controlled current source adjusts the source current of gate based on the current flowing through the first unidirectional conduction device, so as to ensure that the current flowing through the first unidirectional conduction device is equal to the source current of gate. Therefore, the error between the detected current value of the load when reaching the steady state and the reference current value caused by the gate leakage current of the gallium nitride power device is avoided, which ensures that the detected current value of the load when reaching the steady state is equal to the reference current value, and improves the closed-loop control accuracy of the constant-current control of the control circuit, thereby achieving the precise closed-loop control of the load.

In a possible implementation, as shown in FIG. 6, the detection module includes a temperature sampling unit 105 and a temperature error amplifier 106.

The temperature sampling unit 105 is used to sample a temperature of the load 40. An output terminal of the temperature sampling unit 105 is connected to a negative input terminal of the temperature error amplifier 106. A positive input terminal of the temperature error amplifier 106 is used to receive an input reference temperature value TBAT_REG_REF, and an output terminal of the temperature error amplifier 106 is connected to the cathode of the first diode D1, so as to determine that the load reaches the preset state when a sampled temperature value TBAT_SNS of the load 40 is equal to the reference temperature value TBAT_REG_REF.

Based on the above control circuit, a control method applied to the above control circuit is further provided in an embodiment of the present disclosure. Referring to FIG. 9, FIG. 9 is a schematic flowchart of yet another control method provided in an embodiment of the present disclosure. As shown in FIG. 9, S20 above may include S207 to S209.

In S207, the temperature sampling unit samples the temperature of the load.

In S208, the temperature error amplifier determines that the load reaches the preset state when the sampled temperature value of the load is equal to the reference temperature value.

In S209, the temperature error amplifier controls the first unidirectional conduction device to conduct.

In this embodiment, the preset state is a preset over-temperature protection state where the temperature of the load 40 reaches a preset reference temperature. The temperature sampling unit 105 detects the temperature of the load 40, and the temperature error amplifier 106 outputs a high level when the temperature error amplifier 106 determines that the detected temperature value TBAT_SNS is less than the reference temperature value TBAT_REG_REF, so that the first diode D1 is cut off. When the temperature error amplifier 106 determines that the detected temperature value TBAT_SNS is equal to the reference temperature value TBAT_REG_REF, the temperature error amplifier 106 outputs a dedicated level based on a compensation value, so that the first diode D1 conducts. Therefore, the gate voltage of the gallium nitride power device MOS2 is pulled down, which reduces the current flowing through the load and power, thereby ensuring that the temperature of the load no longer rises. Due to the adjustment of the controlled current source 30, after the first diode D1 conducts, the current flowing through the first diode D1 is equal to the source current of gate Isrc, so that an error in the detected temperature value caused by the gate leakage current Ileak is avoided, and the temperature of the load 40 when reaching the steady state reaches the reference temperature value, thereby achieving the precise over-temperature protection of the load 40.

In the control circuit and the control method provided in the above embodiments, the temperature error amplifier controls the first unidirectional conduction device to conduct when the temperature error amplifier determines that the detected temperature value of the load is equal to the reference temperature value, so that the conducting impedance of the gallium nitride power device remains unchanged, which ensures that the temperature of the load no longer rises. The first sampling module samples the current flowing through the first unidirectional conduction device, and the controlled current source adjusts the source current of gate based on the current flowing through the first unidirectional conduction device, so as to ensure that the current flowing through the first unidirectional conduction device is equal to the source current of gate. Therefore, the error between the detected temperature value of the load and the reference temperature value caused by the gate leakage current of the gallium nitride power device is avoided, which improves the closed-loop control accuracy of the over-temperature protection control of the control circuit, thereby achieving the precise closed-loop control of the load.

It should be noted that the output voltage sampling unit and the voltage error amplifier, the output current sampling unit and the current error amplifier, and the temperature sampling unit and the temperature error amplifier in the above embodiments may be arranged in parallel in the control circuit.

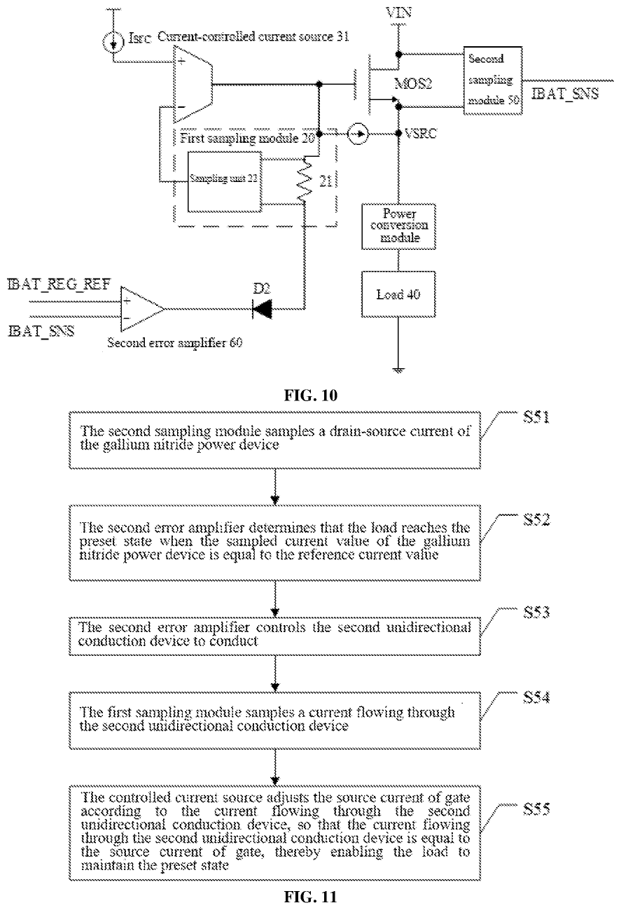

Based on the above embodiments, a control circuit is further provided in an embodiment of the present disclosure. Referring to FIG. 10, FIG. 10 is a schematic diagram of yet another control circuit provided in an embodiment of the present disclosure. As shown in FIG. 10, the detection module 10 further includes a second sampling module 50, a second error amplifier 60, and a second diode D2.

Input terminals of the second sampling module 50 are respectively connected to the drain and the source of the gallium nitride power device MOS2 to form a parallel connection, and an output terminal of the second sampling module 50 is connected to a negative input terminal of the second error amplifier 60. A positive input terminal of the second error amplifier 60 is used to receive an input reference current value, and an output terminal of the second error amplifier 60 is connected to a cathode of the second diode D2, so as to determine that the load 40 reaches the preset state when a sampled current value of the gallium nitride power device MOS2 is equal to a reference current value.

It should be noted that, in addition to the diode shown in FIG. 10, a second unidirectional conduction device may also be other device with a unidirectional current direction, such as a MOS transistor or a triode, which is not limited in this embodiment.

Based on the above control circuit, a control method applied to the above control circuit is further provided in an embodiment of the present disclosure. Referring to FIG. 11, FIG. 11 is a schematic flowchart of yet another control method provided in an embodiment of the present disclosure. As shown in FIG. 11, the method may further include S51 to S55.

In S51, the second sampling module samples a drain-source current of the gallium nitride power device.

In S52, the second error amplifier determines that the load reaches the preset state when the sampled current value of the gallium nitride power device is equal to the reference current value.

In S53, the second error amplifier controls the second unidirectional conduction device to conduct.

In S54, the first sampling module samples a current flowing through the second unidirectional conduction device.

In S55, the controlled current source adjusts the source current of gate according to the current flowing through the second unidirectional conduction device, so that the current flowing through the second unidirectional conduction device is equal to the source current of gate, thereby enabling the load to maintain the preset state.

In this embodiment, as shown in FIGS. 10 and 11, the preset state is a preset over-current protection state where a conducting current of the gallium nitride power device MOS2 reaches a preset current value. The second sampling module 50 detects the drain-source current of the load 40, and the second error amplifier 60 outputs a high level when the second error amplifier 60 determines that a detected current value IBAT_SNS is less than the reference current value IBAT_REG_REF, so that the second diode D2 is cut off. When the second error amplifier 60 determines that the detected current value IBAT_SNS is equal to the reference current value IBAT_REG_REF, the second error amplifier 60 outputs a dedicated level based on a compensation value, so that the second diode D2 conducts. Therefore, the gate voltage of the gallium nitride power device MOS2 is pulled down and remains constant, thereby enabling the conducting impedance of the gallium nitride power device MOS2 to be unchanged, and a gate-source current of the gallium nitride power device MOS2 no longer rises. Due to the adjustment of the controlled current source 30, after the second diode D2 conducts, the current flowing through the second diode D2 is equal to the source current of gate Isrc, so that an error in the detected current value caused by the gate leakage current Ileak is avoided, and the conducting current of the gallium nitride power device MOS2 does not exceed the reference current value, thereby achieving the protection of the gallium nitride power device MOS2 and avoiding the over-current damage of the gallium nitride power device MOS2.

In the control circuit and the control method provided in the above embodiments, the second error amplifier controls the second unidirectional conduction device to conduct when the second error amplifier determines that the detected current value of the gallium nitride power device is equal to the reference current value, so that the gate-source current of the gallium nitride power device MOS2 no longer rises, which avoids a situation that the detected current value of the gallium nitride power device exceeds the reference current value due to the gate leakage current of the gallium nitride power device, thereby achieving the precise protection of the gallium nitride power device and avoiding the over-current damage of the gallium nitride power device.

In a possible implementation, in addition to detecting the gate-source current of the gallium nitride power device MOS2, the detection module composed of the second sampling module 50, the second error amplifier 60, and the second diode D2 may also detect the source voltage of the gallium nitride power device MOS2.

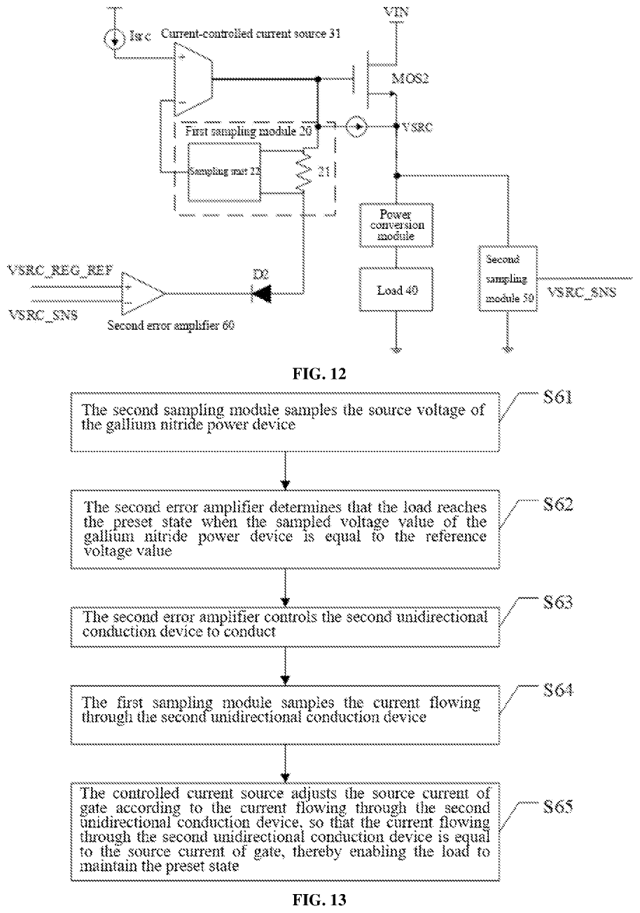

Referring to FIG. 12, FIG. 12 is a schematic diagram of yet another control circuit provided in an embodiment of the present disclosure. As shown in FIG. 12, the input terminals of the second sampling module 50 are connected between the source of the gallium nitride power device MOS2 and the ground, and the output terminal of the second sampling module 50 is connected to the negative input terminal of the second error amplifier 60. The positive input terminal of the second error amplifier 60 is used to receive an input reference voltage value, and the output terminal of the second error amplifier 60 is connected to the cathode of the second diode D2, so as to determine that the load 40 reaches the preset state when a sampled voltage value of the gallium nitride power device MOS2 is equal to the reference voltage value.

Based on the above control circuit, a control method applied to the above control circuit is further provided in an embodiment of the present disclosure. Referring to FIG. 13, FIG. 13 is a schematic flowchart of yet another control method provided in an embodiment of the present disclosure. As shown in FIG. 13, the method may further include S61 to S65.

In S61, the second sampling module samples the source voltage of the gallium nitride power device.

In S62, the second error amplifier determines that the load reaches the preset state when the sampled voltage value of the gallium nitride power device is equal to the reference voltage value.

In S63, the second error amplifier controls the second unidirectional conduction device to conduct.

In S64, the first sampling module samples the current flowing through the second unidirectional conduction device.

In S65, the controlled current source adjusts the source current of gate according to the current flowing through the second unidirectional conduction device, so that the current flowing through the second unidirectional conduction device is equal to the source current of gate, thereby enabling the load to maintain the preset state.

In this embodiment, as shown in FIGS. 12 and 13, the preset state is a preset over-voltage protection state where a conducting voltage of the gallium nitride power device MOS2 reaches a preset voltage value. The second sampling module 50 detects the source voltage of the load 40, and the second error amplifier 60 outputs a high level when the second error amplifier 60 determines that a detected voltage value VSRC_SNS is less than a reference voltage value VSRC_REG_REF, so that the second diode D2 is cut off. When the second error amplifier 60 determines that the detected voltage value VSRC_SNS is equal to the reference voltage value VSRC_REG_REF, the second error amplifier 60 outputs a dedicated level based on a compensation value, so that the second diode D2 conducts. Therefore, the gate voltage of the gallium nitride power device MOS2 is pulled down and remains constant, thereby enabling the conducting impedance of the gallium nitride power device MOS2 to be unchanged, and the source voltage of the gallium nitride power device MOS2 no longer rises. Due to the adjustment of the controlled current source 30, after the second diode D2 conducts, the current flowing through the second diode D2 is equal to the source current of gate Isrc, so that an error in the detected voltage value caused by the gate leakage current Ileak is avoided, and the conducting voltage of the gallium nitride power device MOS2 does not exceed the reference voltage value, thereby achieving the protection of the gallium nitride power device MOS2 and avoiding the over-voltage damage of the gallium nitride power device MOS2.

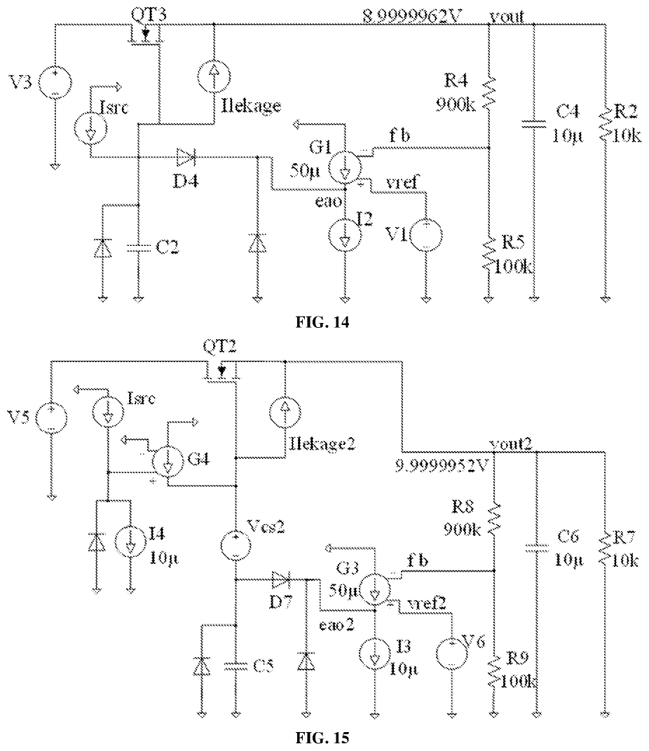

Referring to FIG. 14, FIG. 14 is a schematic simulation diagram based on an existing control circuit of a gallium nitride power device. As shown in FIG. 14, G1 is used to represent the detection module, vref is the positive input terminal of the detection module, and fb is the negative input terminal of the detection module. A divided voltage (with a proportion of 1/10) of a load voltage vout through resistors R4 and R5 is compared with a reference voltage vref, so as to determine whether a detected voltage value VBAT_SNS of a load is equal to a reference voltage value VBAT_REG_REF (which is set to 1 V in this simulation). When the divided voltage of vout through the resistors R4 and R5 is equal to the reference voltage vref, a terminal eao of G1 outputs a low level, and a diode D4 conducts, so that a current having a value of Isource minus Ilekage (Isource-Ilekage) is generated on the diode D4, and VBAT_SNS is 0.9 V when the system is in balance, while VBAT_REG_REF is equal to 1 V (VBAT_REG_REF=1 V). An error caused by the leakage current Ilekage results in an actual voltage value of the load being 8.9999962V, which has a large deviation from the desired output voltage value of 10 V.

Referring to FIG. 15, FIG. 15 is a schematic simulation diagram based on a control circuit of a gallium nitride power device in an embodiment of the present disclosure. As shown in FIG. 15, G3 represents the detection module 10, vref is the positive input terminal of the detection module 10, fb is the negative input terminal of the detection module 10, and eao2 is the output terminal of the detection module 10. A divided voltage (with a proportion of 1/10) of an output voltage vout2 through resistors R9 and R8 is compared with a reference voltage vref2, so as to determine whether a detected voltage value VBAT_SNS of a load is equal to a reference voltage value VBAT_REG_REF. When the divided voltage of vout2 through the resistors R9 and R8 is equal to the reference voltage vref2, the terminal eao2 of G3 outputs a low level, and a diode D7 conducts. G4 represents the controlled current source 30, and Vcs2 represents the first sampling module 20. Vcs2 samples a current flowing through the diode D7 and returns this current to G4. G4 adjusts a source current of gate Isource according to the current flowing through the diode D7, so that a current output to the diode D7 is equal to a set current value I4, and is also equal to a current I3. A current flowing through G3 is 0 when reaching the steady state. At this time, fb and vref2 are completely equal to each other, and an actual voltage value of the load is 9.9999962V, which has only a very small and negligible deviation from the desired voltage value of 10 V.

The above are only specific embodiments of the present disclosure, however, the protection scope of the present disclosure is not limited thereto. Any changes or substitutions that can be easily conceived of by those skilled in the art within the technical scope of the present disclosure shall be covered within the protection scope of the present disclosure. Therefore, the protection scope of the present disclosure shall be subject to the protection scope of the claims.

1. A control circuit, wherein the control circuit comprises a gallium nitride power device, a detection module, a first unidirectional conduction device, first sampling module, and a controlled current source,
wherein a first input terminal of the controlled current source is connected to a source current of gate, and an output terminal of the controlled current source is connected to a gate of the gallium nitride power device to control a gate voltage of the gallium nitride power device;
a drain of the gallium nitride power device is connected to a power supply, and a source of the gallium nitride power device is connected to a load, so as to adjust an output power of the load according to the gate voltage of the gallium nitride power device;
an input terminal of the detection module is connected to the load, so as to detect a state of the load and determine whether the load reaches a preset state according to a detected state value and a reference state value;
an output terminal of the detection module is connected to a cathode of the first unidirectional conduction device to allow the first unidirectional conduction device to conduct when the load is determined to reach the preset state;
an anode of the first unidirectional conduction device is respectively connected to the controlled current source, and the gate and the source of the gallium nitride power device, and the first sampling module is connected between the controlled current source and the first unidirectional conduction device to sample a current flowing through the first unidirectional conduction device; and
a second input terminal of the controlled current source is connected to an output terminal of the first sampling module to adjust the source current of gate according to the current flowing through the first unidirectional conduction device, so that the current flowing through the first unidirectional conduction device is equal to the source current of gate, thereby enabling the load to maintain the preset state.

2. The control circuit according to claim 1, wherein the detection module comprises an output voltage sampling unit and a voltage error amplifier, wherein
input terminals of the output voltage sampling unit are respectively connected to two terminals of the load to sample an output voltage of the load; and
an output terminal of the output voltage sampling unit is connected to a negative input terminal of the voltage error amplifier, a positive input terminal of the voltage error amplifier is configured to receive an input reference voltage value, and an output terminal of the voltage error amplifier is connected to the cathode of the first unidirectional conduction device, so as to determine that the load reaches the preset state when a sampled voltage value of the load is equal to the reference voltage value.

3. The control circuit according to claim 1, wherein the detection module comprises an output current sampling unit and a current error amplifier, and the control circuit further comprises a resistor;
the resistor is connected between the load and the ground, input terminals of the output current sampling unit are respectively connected to two terminals of the resistor to sample an output current of the load; and
an output terminal of the output current sampling unit is connected to a negative input terminal of the current error amplifier, a positive input terminal of the current error amplifier is configured to receive an input reference current value, and an output terminal of the current error amplifier is connected to the cathode of the first unidirectional conduction device, so as to determine that the load reaches the preset state when a sampled current value of the load is equal to the reference current value.

4. The control circuit according to claim 1, wherein the detection module comprises a temperature sampling unit and a temperature error amplifier, wherein
the temperature sampling unit is configured to sample a temperature of the load, an output terminal of the temperature sampling unit is connected to a negative input terminal of the temperature error amplifier, a positive input terminal of the temperature error amplifier is configured to receive an input reference temperature value, and an output terminal of the temperature error amplifier is connected to the cathode of the first unidirectional conduction device, so as to determine that the load reaches the preset state when a sampled temperature value of the load is equal to the reference temperature value.

5. The control circuit according to claim 1, wherein the control circuit further comprises a second sampling module, a second error amplifier and a second unidirectional conduction device, wherein
input terminals of the second sampling module are respectively connected to the drain and the source of the gallium nitride power device to form a parallel connection, an output terminal of the second sampling module is connected to a negative input terminal of the second error amplifier, a positive input terminal of the second error amplifier is configured to receive an input reference current value, and an output terminal of the second error amplifier is connected to a cathode of the second unidirectional conduction device, so as to determine that the load reaches the preset state when a sampled current value of the gallium nitride power device is equal to the reference current value.

6. The control circuit according to claim 5, wherein the input terminals of the second sampling module are connected in parallel between the source of the gallium nitride power device and the ground, the output terminal of the second sampling module is connected to the negative input terminal of the second error amplifier, the positive input terminal of the second error amplifier is configured to receive an input reference voltage value, and the output terminal of the second error amplifier is connected to the cathode of the second unidirectional conduction device, so as to determine that the load reaches the preset state when a sampled voltage value of the gallium nitride power device is equal to the reference voltage value.

7. A control method, wherein the control method is applicable to the control circuit according to claim 1, the control circuit comprises the gallium nitride power device, the detection module, the first unidirectional conduction device, the first sampling module, and the controlled current source; the control method comprises:
controlling, by the controlled current source, the gate voltage of the gallium nitride power device according to the source current of gate, so as to adjust the output power of the load according to the gate voltage of the gallium nitride power device;
detecting, by the detection module, the state of the load, and determining, by the detection module, that the load reaches the preset state according to the detected state value and the reference state value, so as to allow the first unidirectional conduction device to conduct;
sampling, by the first sampling module, the current flowing through the first unidirectional conduction device; and
adjusting, by the controlled current source, the source current of gate according to the current flowing through the first unidirectional conduction device, so that the current flowing through the first unidirectional conduction device is equal to the source current of gate, thereby enabling the load to maintain the preset state.

8. The control method according to claim 7, wherein the detection module comprises an output voltage sampling unit and a voltage error amplifier; the step of detecting, by the detection module, the state of the load, and determining, by the detection module, that the load reaches the preset state according to the detected state value and the reference state value, so as to allow the first unidirectional conduction device to conduct, comprises:
sampling, by the output voltage sampling unit, an output voltage of the load;
determining, by the voltage error amplifier, that the load reaches the preset state when a sampled voltage value of the load is equal to a reference voltage value; and
controlling, by the voltage error amplifier, the first unidirectional conduction device to conduct.

9. The control method according to claim 7, wherein the detection module comprises an output current sampling unit and a current error amplifier; the step of detecting, by the detection module, the state of the load, and determining, by the detection module, that the load reaches the preset state according to the detected state value and the reference state value, so as to allow the first unidirectional conduction device to conduct, comprises:
sampling, by the output current sampling unit, an output current of the load;
determining, by the current error amplifier, that the load reaches the preset state when a sampled current value of the load is equal to a reference current value; and
controlling, by the current error amplifier, the first unidirectional conduction device to conduct.

10. The control method according to claim 7, wherein the detection module comprises a temperature sampling unit and a temperature error amplifier; the step of detecting, by the detection module, the state of the load, and determining, by the detection module, that the load reaches the preset state according to the detected state value and the reference state value, so as to allow the first unidirectional conduction device to conduct, comprises:
sampling, by the temperature sampling unit, a temperature of the load;
determining, by the temperature error amplifier, that the load reaches the preset state when a sampled temperature value of the load is equal to a reference temperature value; and
controlling, by the temperature error amplifier, the first unidirectional conduction device to conduct.

11. The control method according to claim 7, wherein the control circuit further comprises a second sampling module, a second error amplifier and a second unidirectional conduction device, and input terminals of the second sampling module are respectively connected to the drain and the source of the gallium nitride power device; the control method further comprises:
sampling, by the second sampling module, a drain-source current of the gallium nitride power device;
determining, by the second error amplifier, that the load reaches the preset state when a sampled current value of the gallium nitride power device is equal to a reference current value;
controlling, by the second error amplifier, the second unidirectional conduction device to conduct;
sampling, by the first sampling module, a current flowing through the second unidirectional conduction device; and
adjusting, by the controlled current source, the source current of gate according to the current flowing through the second unidirectional conduction device, so that the current flowing through the second unidirectional conduction device is equal to the source current of gate, thereby enabling the load to maintain the preset state.

12. The control method according to claim 11, wherein the input terminals of the second sampling module are connected between the source of the gallium nitride power device and the ground, and the control method further comprises:
sampling, by the second sampling module, a source voltage of the gallium nitride power device;
determining, by the second error amplifier, that the load reaches the preset state when a sampled voltage value of the gallium nitride power device is equal to a reference voltage value;
controlling, by the second error amplifier, the second unidirectional conduction device to conduct;
sampling, by the first sampling module, a voltage flowing through the second unidirectional conduction device; and
adjusting, by the controlled current source, the source current of gate according to the current flowing through the second unidirectional conduction device, so that the current flowing through the second unidirectional conduction device is equal to the source current of gate, thereby enabling the load to maintain the preset state.

13. The control method according to claim 7, wherein the detection module comprises an output voltage sampling unit and a voltage error amplifier, wherein
input terminals of the output voltage sampling unit are respectively connected to two terminals of the load to sample an output voltage of the load; and
an output terminal of the output voltage sampling unit is connected to a negative input terminal of the voltage error amplifier, a positive input terminal of the voltage error amplifier is configured to receive an input reference voltage value, and an output terminal of the voltage error amplifier is connected to the cathode of the first unidirectional conduction device, so as to determine that the load reaches the preset state when a sampled voltage value of the load is equal to the reference voltage value.

14. The control method according to claim 7, wherein the detection module comprises an output current sampling unit and a current error amplifier, and the control circuit further comprises a resistor;
the resistor is connected between the load and the ground, input terminals of the output current sampling unit are respectively connected to two terminals of the resistor to sample an output current of the load; and
an output terminal of the output current sampling unit is connected to a negative input terminal of the current error amplifier, a positive input terminal of the current error amplifier is configured to receive an input reference current value, and an output terminal of the current error amplifier is connected to the cathode of the first unidirectional conduction device, so as to determine that the load reaches the preset state when a sampled current value of the load is equal to the reference current value.

15. The control method according to claim 7, wherein the detection module comprises a temperature sampling unit and a temperature error amplifier, wherein
the temperature sampling unit is configured to sample a temperature of the load, an output terminal of the temperature sampling unit is connected to a negative input terminal of the temperature error amplifier, a positive input terminal of the temperature error amplifier is configured to receive an input reference temperature value, and an output terminal of the temperature error amplifier is connected to the cathode of the first unidirectional conduction device, so as to determine that the load reaches the preset state when a sampled temperature value of the load is equal to the reference temperature value.

16. The control method according to claim 7, wherein the control circuit further comprises a second sampling module, a second error amplifier and a second unidirectional conduction device, wherein
input terminals of the second sampling module are respectively connected to the drain and the source of the gallium nitride power device to form a parallel connection, an output terminal of the second sampling module is connected to a negative input terminal of the second error amplifier, a positive input terminal of the second error amplifier is configured to receive an input reference current value, and an output terminal of the second error amplifier is connected to a cathode of the second unidirectional conduction device, so as to determine that the load reaches the preset state when a sampled current value of the gallium nitride power device is equal to the reference current value.

17. The control method according to claim 16, wherein the input terminals of the second sampling module are connected in parallel between the source of the gallium nitride power device and the ground, the output terminal of the second sampling module is connected to the negative input terminal of the second error amplifier, the positive input terminal of the second error amplifier is configured to receive an input reference voltage value, and the output terminal of the second error amplifier is connected to the cathode of the second unidirectional conduction device, so as to determine that the load reaches the preset state when a sampled voltage value of the gallium nitride power device is equal to the reference voltage value.
